(19) United States
(12) Patent Application Publication
(10) Pub. No.: US 2025/0385422 A1
(43) Pub. Date: Dec. 18, 2025

(54) ELECTRONIC DEVICE

(71) Applicant: Advanced Semiconductor Engineering, Inc., Kaohsiung (TW)

(72) Inventors: Shao-En HSU, Kaohsiung (TW); Huei-Shyong CHO, Kaohsiung (TW)

(73) Assignee: Advanced Semiconductor Engineering, Inc., Kaohsiung (TW)

(21) Appl. No.: 18/746,017

(22) Filed: Jun. 17, 2024

(51) Int. Cl. H01Q 1/22; H01L 23/66; H01Q 9/04; H03F 3/24; H04B 1/40

(52) U.S. Cl. CPC H01Q 1/2283; H01L 23/66; H01Q 9/0407; H03F 3/245; H01L 2223/6616; H01L 2223/6677; H03F 2200/294; H03F 2200/451; H04B 1/40

(57) ABSTRACT

An electronic device is provided. The electronic device includes a carrier, an antenna component, and a transceiver. The carrier has a first surface. The antenna component is disposed over the first surface of the carrier. The transceiver is disposed over the first surface of the carrier and configured to transmit signals to the antenna component by the carrier.

### BACKGROUND

### 1. Field of the Disclosure

The present disclosure relates to an electronic device.

### 2. Description of the Related Art

A transceiver can integrate phase shifters and power amplifiers using the same technology node to reduce its form factor. However, with the increasing bandwidth demands of transceivers in advanced wireless communications, e.g., beyond 5G (B5G), greater numbers of phase shifters and power amplifiers are required. This leads to higher layout density, which adversely impacts the thermal dissipation.

### SUMMARY

In some embodiments, an electronic device includes a carrier, an antenna component, and a transceiver. The carrier has a first surface. The antenna component is disposed over the first surface of the carrier. The transceiver is disposed over the first surface of the carrier and configured to transmit signals to the antenna component by the carrier.

In some embodiments, an electronic device includes an antenna component, a power amplifier, and a radio frequency circuit. The power amplifier is electrically connected to the antenna component. The radio frequency circuit is electrically connected to the power amplifier At least two of the antenna component, the power amplifier, and the radio frequency circuit are free from overlapping each other.

In some embodiments, an electronic device includes a carrier, an antenna component, and a transceiver. The antenna component is disposed over the carrier. The transceiver includes a first electronic component with a first technical node and a second electronic component with a second technical node. The first electronic component is disposed over the carrier. The second electronic component is disposed over the carrier. The first electronic component is separated from the second electronic component and configured to enhance a thermal dissipation of the second electronic component.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 is a cross-sectional view of an electronic device according to some embodiments of the present disclosure.

FIG. 1A is a top view of an electronic device according to some embodiments of the present disclosure.

FIG. 1B is a top view of an electronic device according to some embodiments of the present disclosure.

FIG. 2 illustrates signal transmission path(s) of an electronic device according to some embodiments of the present disclosure.

FIG. 2A illustrates signal transmission path(s) of an electronic device according to some embodiments of the present disclosure.

FIG. 3 is a cross-sectional view of an electronic device according to some embodiments of the present disclosure.

FIG. 4 is a schematic diagram of an electronic device according to some embodiments of the present disclosure.

FIG. 5 is a cross-sectional view of an electronic device according to some embodiments of the present disclosure.

FIG. 6 is a cross-sectional view of an electronic device according to some embodiments of the present disclosure.

FIG. 7 is a cross-sectional view of an electronic device according to some embodiments of the present disclosure.

FIG. 8 is a cross-sectional view of an electronic device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

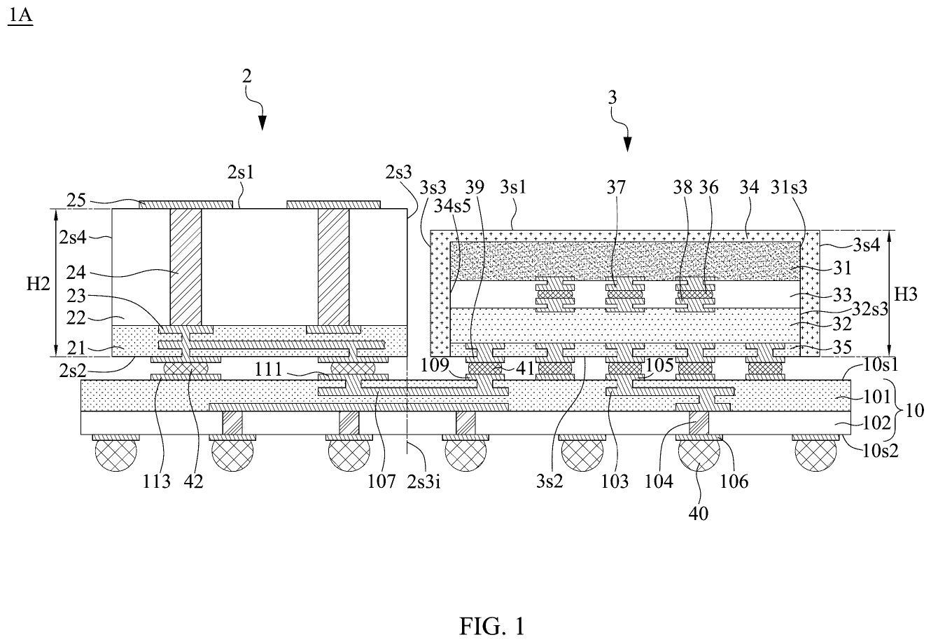

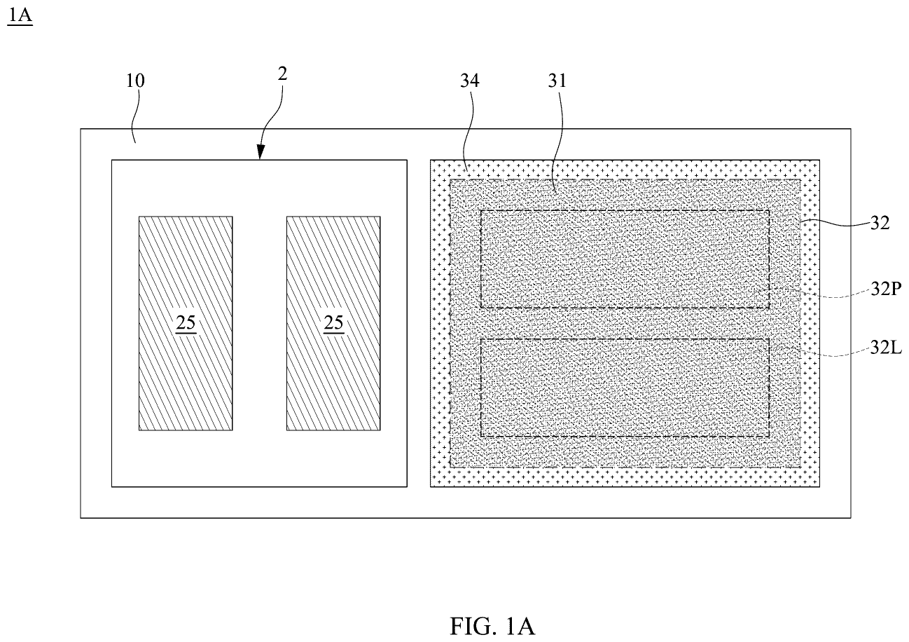

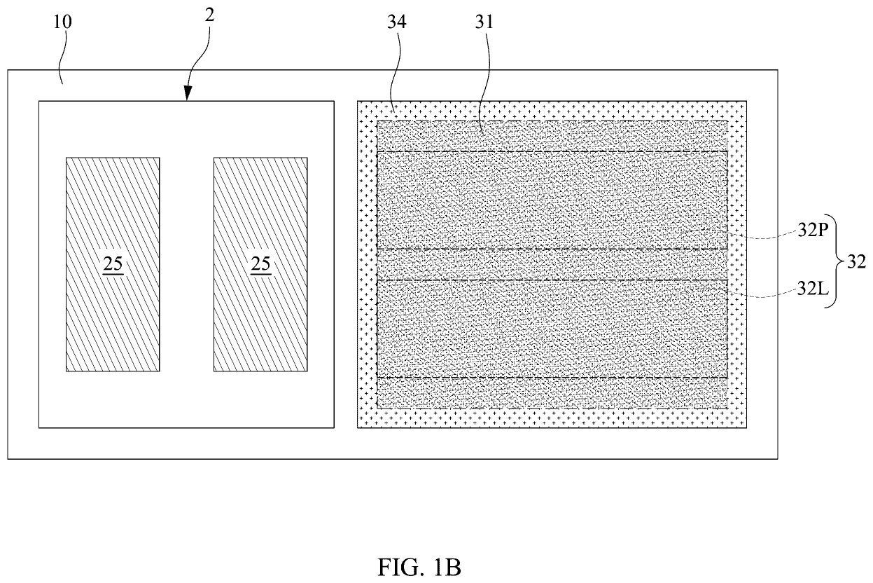

FIG. 1 is a cross-sectional view of an electronic device 1A according to some embodiments of the present disclosure. The electronic device 1A may include a carrier 10, an antenna component 2, a transceiver 3, and a plurality of terminals 40. The carrier 10 may be electrically connected to the antenna component 2. The carrier 10 may be electrically connected to the transceiver 3. The terminals 40 may electrically connect the carrier 10 to an external electronic component (not shown). The electronic device 1A may be electrically connected to an external device through an external circuit board.

The carrier 10 (or a substrate, a circuit structure) 10 may be disposed below the antenna component 2 and the transceiver 3. The carrier 10 may have a first surface 10s1 and a second surface 10s2 opposite thereto. The antenna component 2 and the transceiver 3 may be disposed over the first surface 10s1. In some embodiments, the carrier 10 may include an interposer. In some embodiments, the carrier 10 may include, for example, a printed circuit board (PCB), such as a paper-based copper foil laminate, a composite copper foil laminate, or a polymer-impregnated glass-fiber-based copper foil laminate.

The carrier 10 may include a dielectric layer 102. The redistribution layer 101 may be disposed over the dielectric layer 102. The carrier 10 may include a plurality of conductive pillars 104 disposed in the dielectric layer 102. The conductive pillars 104 may extend through the dielectric layer 102. The carrier 10 may include a plurality of conductive pads (or pads) 106 disposed at the second surface 10s2 of the carrier 10. The conductive pillars 104 may contact the conductive pads 106. The conductive pillars 104 may electrically connect the redistribution layer 101 to the conductive pads 106. The terminals 40 may be disposed over the second surface 10s2 of the carrier 10. The conductive pads 106 may be electrically connected to the terminals 40.

The dielectric layer 102 may include, for example, silicon oxide (SiO₂), silicon nitride (Si₃N₄), silicon oxynitride (N₂OSi₂), silicon nitride oxide (N₂OSi₂), or other suitable materials. The conductive pillars 104 may be made of metal, such as copper, gold, silver, aluminum, titanium, tantalum, or the like. The conductive pads 106 may be made of metal, such as copper, gold, silver, aluminum, titanium, tantalum, or the like. The terminals 40 may include solder balls, controlled collapse chip connection (C4) bumps, a ball grid array (BGA), or a land grid array (LGA).

The carrier 10 may include a redistribution layer (RDL) 101. The redistribution layer 101 may be disposed at the first surface 10s1 of the carrier 10. The redistribution layer 101 may include one or more dielectric layers (not annotated in the figures). The redistribution layer 101 may include an interconnection structure (or a conductive trace) 103 and an interconnection structure (or a conductive trace) 107 disposed in the one or more dielectric layers of the redistribution layer 101.

The carrier 10 may include a plurality of conductive pads (or pads) 105, 109, 111, and 113. The conductive pads 105, 109, 111, and 113 may be disposed at the first surface 10s1 of the carrier 10. The conductive pads 105 may be electrically connected to the interconnection structure 103 of the redistribution layer 101. The conductive pads 105 may be electrically connected to the transceiver 3 through a plurality of connection elements 41. The connection elements 41 may be disposed between the transceiver 3 and the carrier 10 or between the transceiver 3 and the interconnection structure 103.

The conductive pads 109 may be electrically connected to the interconnection structure 107 of the redistribution layer 101. The conductive pads 109 may be electrically connected to the transceiver 3 through the plurality of connection elements 41. The connection elements 41 may be disposed between the transceiver 3 and the interconnection structure 107. The conductive pads 111 may be electrically connected to the interconnection structure 107 of the redistribution layer 101. The conductive pads 111 may be electrically connected to the antenna component 2 through the plurality of connection elements 42. The connection elements 42 may be disposed between the antenna component 2 and the carrier 10 or between the antenna component 2 and the interconnection structure 107. The conductive pads 113 may be electrically connected to the carrier 10.

The one or more dielectric layers of the redistribution layer 101 may include, for example, silicon oxide (SiO₂), silicon nitride (Si₃N₄), silicon oxynitride (N₂OSi₂), silicon nitride oxide (N₂OSi₂), or other suitable materials. The conductive pads 105, 109, 111, and 113 may be made of metal, such as copper, gold, silver, aluminum, titanium, tantalum, or the like. The interconnection structure 103 may be made of metal, such as copper, gold, silver, aluminum, titanium, tantalum, or the like. The interconnection structure 107 may be made of metal, such as copper, gold, silver, aluminum, titanium, tantalum, or the like. The connection elements 41 and 42 may include solder balls, controlled collapse chip connection (C4) bumps, a ball grid array (BGA), or a land grid array (LGA).

The redistribution layer 101 of the carrier 10 may be electrically connected to the transceiver 3 through the interconnection structure 103. The redistribution layer 101 of the carrier 10 may be electrically connected to the antenna component 2 through the interconnection structure 107. The redistribution layer 101 of the carrier 10 may be electrically connected to the transceiver 3 through the interconnection structure 107.

The interconnection structure 107 may extend in a direction substantially parallel to the first surface 10s1 of the carrier 10. The interconnection structure 107 may be disposed below the antenna component 2 and the transceiver 3. The interconnection structure 107 may electrically connect the transceiver 3 to the antenna component 2. The interconnection structure 107 may be a bridge for the connection between the transceiver 3 and the antenna component 2. In some embodiments, the antenna component 2 may have a first lateral surface 2s3 facing the transceiver 3 and substantially perpendicular to the first surface 10s1 of the carrier 10. An imaginary extension line 2s3i of the first lateral surface 2s3 may pass through the interconnection structure 107. In other words, the interconnection structure 107 has a projection area over a top surface 2s1 of the antenna component 2 and overlapping the first lateral surface 2s3 and a portion of the top surface 2s1.

The antenna component 2 may be disposed on or over the carrier 10 (or the first surface 10s1). The antenna component 2 may have a top surface 2s1 facing away from the first surface 10s1 and a bottom surface 2s2 opposite to the top surface 2s1. The bottom surface 2s2 of the antenna component 2 may face the carrier 10 or the first surface 10s1. The antenna component 2 may have a first lateral surface 2s3 facing the transceiver 3 and a second lateral surface 2s4 opposite to the first lateral surface 2s3. There may be no electrical connections at the first lateral surface 2s3 and the second lateral surface 2s4. The first lateral surface 2s3 and the second lateral surface 2s4 may extend between the top surface 2s1 and the bottom surface 2s2. In some embodiments, the antenna component 2 may be electrically connected to the carrier 10 through the connection elements 42.

In some embodiments, the antenna component 2 may be configured to radiate and/or receive electromagnetic signals, such as radio frequency (RF) signals. For example, the antenna component 2 may be configured to operate in a frequency between about 10 GHz and about 40 GHz, such as 10 GHz, 20 GHz, 30 GHz, or 40 GHz. In some embodiments, the antenna component 2 may be configured to operate in a frequency between about 30 GHz and about 300 GHz. In some embodiments, the antenna component 2 may be configured to operate in a frequency between about 300 GHz and about 10 THz. In some embodiments, the antenna component 2 may support fifth generation (5G) communications, such as Sub-6 GHz frequency bands and/or millimeter (mm) wave frequency bands. For example, the antenna component 2 may incorporate both Sub-6 GHz antennas and mm wave antennas. In some embodiments, the antenna component 2 may support beyond-5G or 6G communications, such as terahertz (THz) frequency bands.

In some embodiments, the antenna component 2 may include a redistribution layer 21, a substrate 22, an antenna pattern 25, and a through-via 24.

The redistribution layer 21 may be disposed below the substrate 22. The redistribution layer 21 may include one or more dielectric layers (not annotated in the figures) and a plurality of traces 23 embedded therein. The redistribution layer 21 may include one or more pads (not annotated in the figures) electrically connected to the connection elements 42.

The substrate 22 may include pre-impregnated composite fibers or ceramic-filled polytetrafluoroethylene (PTFE) composites, liquid crystal polymer laminate, polyimide-based films, or other suitable materials. The through-via 24 may extend through the substrate 22. The through-via 24 may be a feeding port of the antenna pattern 25. The through-via 24 and a plurality of traces 23 may be configured to transmit the signal(s) from the transceiver 3 to the antenna pattern 25 or transmit the signal(s) from the antenna pattern 25 to the transceiver 3.

The antenna pattern 25 may be disposed on the top surface 2s1 of the antenna component 2. In some embodiments, the antenna pattern 25 may be configured to radiate and/or receive electromagnetic signals, such as RF signals. In some embodiments, the antenna pattern 25 may include an antenna array. In some embodiments, the antenna pattern 25 may include a patch antenna.

The through-via 24 may be made of metal, such as copper, gold, silver, aluminum, titanium, tantalum, or the like. The antenna pattern 25 may be made of metal, such as copper, gold, silver, aluminum, titanium, tantalum, or the like.

The transceiver 3 may be disposed on or over the carrier 10 (or the first surface 10s1). The transceiver 3 and the antenna component 2 may be arranged side by side. The transceiver 3 may have a top surface 3s1 and a bottom surface 3s2 opposite to the top surface 3s1. The top surface 3s1 may be configured to dissipate the heat from the transceiver 3. The bottom surface 3s2 of the transceiver 3 may face the carrier 10 or the first surface 10s1. The transceiver 3 may include a plurality of conductive elements 39 at the bottom surface 3s2 of the transceiver 3. In some embodiments, the conductive elements 39 of the transceiver 3 may be electrically connected to the carrier 10 through the connection elements 41. The conductive elements 39 may be disposed in a dielectric layer 35. The dielectric layer 35 may be disposed at the bottom surface 3s2 of the transceiver 3. The conductive elements 39 may include one or more traces or one or more pads disposed on the dielectric layer 35.

The dielectric layer 35 may include, for example, silicon oxide (SiO₂), silicon nitride (Si₃N₄), silicon oxynitride (N₂OSi₂), silicon nitride oxide (N₂OSi₂), or other suitable materials. The conductive elements 39 may be made of metal, such as copper, gold, silver, aluminum, titanium, tantalum, or the like.

The bottom surface 3s2 of the transceiver 3 and the bottom surface 2s2 of the antenna component 2 may be substantially coplanar. The top surface 3s1 of the transceiver 3 and the top surface 2s1 of the antenna component 2 may face the same direction. The antenna component 2 may have a height H2 defined by the top surface 2s1 and the bottom surface 2s2. The transceiver 3 may have a height H3 defined by the top surface 3s1 and the bottom surface 3s2. The height H2 may be different from the height H3. The height H2 may be greater than the height H3. In some embodiments, an elevation of the top surface 3s1 of the transceiver 3 may be between an elevation of the top surface 2s1 of the antenna component 2 and an elevation of the first surface 10s1 of the carrier 10.

The transceiver 3 may have a first lateral surface 3s3 facing the antenna component 2 and a second lateral surface 3s4 opposite to the first lateral surface 3s3. There may be no electrical connections at the first lateral surface 3s3 and the second lateral surface 3s4. The first lateral surface 3s3 of the transceiver 3 may face the first lateral surface 2s3 of the antenna component 2. The first lateral surface 3s3 and the second lateral surface 3s4 may extend between the top surface 3s1 and the bottom surface 3s2.

The transceiver 3 may be configured to process the signals (or RF signals) from the antenna component 2 before such signals are transmitted to logic circuits, such as an analog-digital converter, CPU, GPU, etc. The transceiver 3 may be configured to transmit signals to the antenna component 2 by the carrier 10. The transceiver 3 may be configured to process the signals from logic circuits before such signals are transmitted to the antenna component 2. The transceiver 3 may be configured to amplify the signals from the logic circuits (through the carrier 10). The transceiver 3 may be configured to adjust the phase/frequency of the signals from the logic circuits (through the carrier 10). The transceiver 3 may be configured to adjust the phase/frequency of the signals from the antenna component 2. The transceiver 3 may be configured to filter the noise of the signals from the antenna component 2.

The transceiver 3 may include an electronic component (or a first electronic component) 31 and an electronic component (or a second electronic component) 32. The electronic component 31 may be electrically connected to the electronic component 32. The electronic component 32 may be electrically connected to the antenna component 2. The electronic component 31 may be configured to operate in a first function. The electronic component 32 is configured to operate in a second function distinct from the first function. The electronic component 32 may be separated from the electronic component 31.

The electronic component 31 may include active devices such as transistors and/or passive devices such as resistors, capacitors, inductors, or a combination thereof. The electronic component 31 may include a radio frequency circuit. The radio frequency circuit of the electronic component 31 may include a phase shifter or an array of phase shifters. The electronic component 31 may be configured to adjust the phase of the signals from the antenna component 2 or from the other logic circuits. In some embodiments, the electronic component 31 may include a radio frequency integrated circuit (RFIC), an application-specific IC (ASIC), a central processing unit (CPU), a microprocessor unit (MPU), a graphics processing unit (GPU), a microcontroller unit (MCU), a field-programmable gate array (FPGA), or another type of IC.

The electronic component 31 may be fabricated with a first technical node. The first technical node may be a CMOS technical node. In some embodiments, the electronic component 31 may include silicon, germanium, and a combination thereof. For example, the electronic component 31 may be a 5 nm or less node wafer, such as a 3 nm or less node wafer, a 2 nm or less node wafer, or less; and the memory element may be a 20 nm or more node wafer, such as a 28 nm or more node wafer, a 32 nm or more node wafer, or greater.

The electronic component 32 may be a chip or a die including a semiconductor substrate, one or more integrated circuit (IC) devices and one or more overlying interconnection structures therein. The IC devices may include active devices such as transistors and/or passive devices such as resistors, capacitors, inductors, or a combination thereof. For example, the electronic component 32 may include a power amplifier or an array of power amplifiers. In some embodiments, the electronic component 32 may be configured to receive an electrical signal and amplify the power of the electrical signal. For example, the electronic component 32 may be configured to receive a radio frequency (RF) signal and amplify the power of the RF signal. In some embodiments, the electronic component 32 may be configured to receive the signal from the electronic component 31. In some embodiments, the electronic component 32 may be configured to amplify the power of the signal from the electronic component 31. In some embodiments, the electronic component 32 may also be referred to as a power amplifying die.

The electronic component 32 may be fabricated with a second technical node. The second technical node may be an III-V technical node. In some embodiments, the electronic component 32 may include a group III-V structure. The electronic component 32 may include, but is not limited to, a group III nitride, for example, a compound InₓAl_{y}Ga_{1-x-y}N, in which x+y≤1. The group III nitride further includes, but is not limited to, for example, a compound Al_{y}Ga_{(1-y)}N, in which y≤1. In some embodiments, the electronic component 32 may include a gallium nitride (GaN) substrate or other suitable substrates.

The electronic component (or the power amplifier) 32 with the second technical node (or the III-V technical node) can enhance the power conversion efficiency as compared to an amplifier fabricated with CMOS technical node. The second technical node may have higher carrier mobility than the first technical node. The power consumption of the electronic component (or the power amplifier) 32 with the second technical node (or the III-V technical node) can be relatively low in the high frequency application. The noise of the electronic component (or the power amplifier) 32 with the second technical node (or the III-V technical node) is inherently lower than an amplifier fabricated with the CMOS technical node. The electronic component (or the power amplifier) 32 with the second technical node (or the III-V technical node) can operate in a temperature range wider than an amplifier fabricated with the CMOS technical node.

In some cases, a transceiver includes an array of power amplifiers and an array of phase shifters fabricated with the same technical node. They are integrated to reduce the size of the transceiver. However, as the numbers of power amplifiers and phase shifters increase to meet the bandwidth requirements of advanced communication schemes, e.g., beyond 5G, the layout density would inevitably increase, which would impact the thermal dissipation of the transceiver and the power conversion efficiency. In the present disclosure, the electronic component 31 with the first technical node and the electronic component 32 with the second technical node are fabricated individually. It provides the flexibility for arranging electronic component 31 and the electronic component 32 in the electronic device 1A. The electronic component 31 may be separated from the electronic component 32 and configured to enhance a thermal dissipation of the electronic component 32. The electronic component 31 and the electronic component 32 are arranged to enhance the thermal dissipation of the electronic device 1A.

In some embodiments, the electronic component 31 may be disposed over the carrier 10 or the first surface 10s1. The electronic component 32 may be disposed over the carrier 10 or the first surface 10s1. In some embodiments, the electronic component 31 may be disposed over the electronic component 32. The electronic component 31 may be stacked over the electronic component 32. The electronic component 31 and the electronic component 32 may be disposed between elevations of the top surface 2s1 and the bottom surface 2s2 of the antenna component 2.

The electronic component 31 may be electrically connected to the electronic component 32. The transceiver 3 may include a connection structure between the electronic component 31 and the electronic component 32, the connection structure having an underfill 33, a plurality of connection elements 36, and a plurality of conductive elements 37 and 38.

The connection elements 36 (or a conductive layer) may be disposed outside the carrier 10 and electrically connect the electronic component 31 to the electronic component 32. The connection elements 36 may be disposed between the conductive elements 37 and 38. The underfill 33 may encapsulate the connection elements 36 and the conductive elements 37 and 38. The conductive elements 37 may connect the electronic component 31 to the connection elements 36. The conductive elements 38 may connect the electronic component 32 to the connection elements 36. The electronic component 31 and the electronic component 32 may be electrically connected through the connection elements 36 and the conductive elements 37 and 38.

The conductive elements 37 and 38 may be made of metal, such as copper, gold, silver, aluminum, titanium, tantalum, or the like. The connection elements 36 may include solder balls, controlled collapse chip connection (C4) bumps, a ball grid array (BGA), or a land grid array (LGA).

In some embodiments, the conductive element 37 and 38 may be respectively disposed within an insulating layer. The conductive element 37 and the corresponding insulating layer are bonded on the conductive element 38 and the corresponding insulating layer in a hybrid bonding manner. The bonding of the conductive elements 37 and 38 may include a copper to copper bonding. The conductive element 37 may be directly bonded on the conductive element 38 without a connection element (e.g., solder). The equivalent resistance of the transmission path between the electronic component 31 and the electronic component 32 can be reduced.

The transceiver 3 may include an encapsulation layer 34. The encapsulation layer 34 may cover the electronic component (or the radio frequency circuit) 31 and the electronic component (or the power amplifier) 32. The encapsulation layer 34 has an inner surface 34s5 in contact with the electronic component (or the radio frequency circuit) 31 and the electronic component (or the power amplifier) 32. The inner surface 34s5 may contact a top surface and a lateral surface 31s3 of the electronic component 31. The inner surface 34s5 may contact a lateral surface 32s3 of the electronic component 32.

In some embodiments, the encapsulation layer 34 may include an epoxy resin including fillers, a molding compound (e.g., an epoxy molding compound or other molding compound), polyimide, a phenolic compound or material, a material including silicone dispersed therein, or a combination thereof.

The electronic component 31, the electronic component 32, and the antenna component 2 may be disposed on the same side of the carrier 10 (i.e., the first surface 10s1). The electronic component 31 and the antenna component 2 may be arranged side by side. The electronic component 32 and the antenna component 2 may be arranged side by side. The first lateral surface 2s3 of the antenna component 2 may face the electronic component 31 and the electronic component 32. At least two of the antenna component 2, the electronic component (or the power amplifier) 32, and the electronic component (or the radio frequency circuit) 31 may be free from overlapping each other. In some embodiments, the antenna component 2 may be free from overlapping the electronic component (or the power amplifier) 32 in a direction substantially perpendicular to the first surface 10s1 of the carrier 10. In some embodiments, the antenna component 2 may be free from overlapping the electronic component (or the radio frequency circuit) 31 in a direction substantially perpendicular to the first surface 10s1 of the carrier 10. In some embodiments, the electronic component (or the power amplifier) 32 may overlap the electronic component (or the radio frequency circuit) 31 in a direction substantially perpendicular to the first surface 10s1 of the carrier 10.

The antenna pattern 25 may be free from overlapping the electronic component (or the power amplifier) 32 in a direction substantially perpendicular to the top surface 2s1 of the antenna component 2. The antenna pattern 25 may be free from overlapping the electronic component (or the radio frequency circuit) 31 in a direction substantially perpendicular to the top surface 2s1 of the antenna component 2.

The interconnection structure 107 of the carrier 10 may be configured to electrically connect the electronic component 32 and the antenna component 2. The interconnection structure 107 may extend in a direction substantially parallel to the bottom surface 2s2 of the antenna component 2 or the bottom surface 3s2 of the transceiver 2. The interconnection structure 107 may be disposed below the electronic component 32 and the antenna component 2. The interconnection structure 107 may electrically connect the electronic component 32 to the antenna component 2. The interconnection structure 107 may be a bridge for the connection between the electronic component 32 and the antenna component 2. The interconnection structure 107 has a projection area over the top surface 2s1 of the antenna component 2 and the top surface 3s1 of the transceiver 3.

In some cases, a transceiver includes an array of power amplifiers and an array of phase shifters fabricated with the same technical node. They are integrated to reduce the size of the transceiver. However, as the numbers of power amplifiers and phase shifters increase to meet the bandwidth requirements of advanced communication schemes, e.g., beyond 5G, the number of pins would inevitably increase. As such, transmission paths would be longer, which would adversely increase transmission loss. In the present disclosure, the electronic component (or the power amplifier) 32 is electrically connected to the antenna component 2 through the interconnection structure 107 of the redistribution layer 101 of the carrier 10. The transmission path between the electronic component 32 and the antenna component 2 can be shortened to improve the transmission loss. The redistribution layer 101 fan-outs the pins (e.g., the pads 39) of the electronic component 32, and thus the electronic component 32 can be closer to the antenna component 2. As a result, the transmission path therebetween can be shorter, the transmission loss can be reduced, and the transmission gain can be improved.

FIG. 1A is a top view of an electronic device (e.g., the electronic device 1A) according to some embodiments of the present disclosure. The electronic component 32 may include a power amplifying region 32P and a low noise amplifying region 32L. The power amplifying region 32P may include a power amplifier or an array of power amplifiers. The low noise amplifying region 32L may include a low noise amplifier or an array of low noise amplifiers. The power amplifier of the power amplifying region 32P and the low noise amplifier of the low noise amplifying region 32L may be integrated. The power amplifying region 32P may be configured to amplify the signals from the electronic component 31. The low noise amplifying region 32L may be configured to amplify the signals and reduce the noise from the antenna component 2.

In some embodiments, the electronic device may include a duplexer (not shown) that allows for two-way communication over a single channel by separating the transmit and receive signals. The duplexer may be configured to separate the signals from the electronic component 31 and the antenna component 2.

The antenna pattern 25 may include a plurality of patch antennas. The antenna pattern 25 may have a rectangular shape in the top view. In some embodiments, the antenna pattern 25 may have an annular ring shape, a triangular shape, or a circular shape, etc.

FIG. 1B is a top view of an electronic device (e.g., the electronic device 1A) according to some embodiments of the present disclosure. The electronic component 32 may include a power amplifier 32P and a low noise amplifier 32L separated from each other. The power amplifier region 32P may be configured to amplify the signals from the electronic component 31. The low noise amplifier 32L may be configured to amplify the signals and reduce the noise from the antenna component 2.

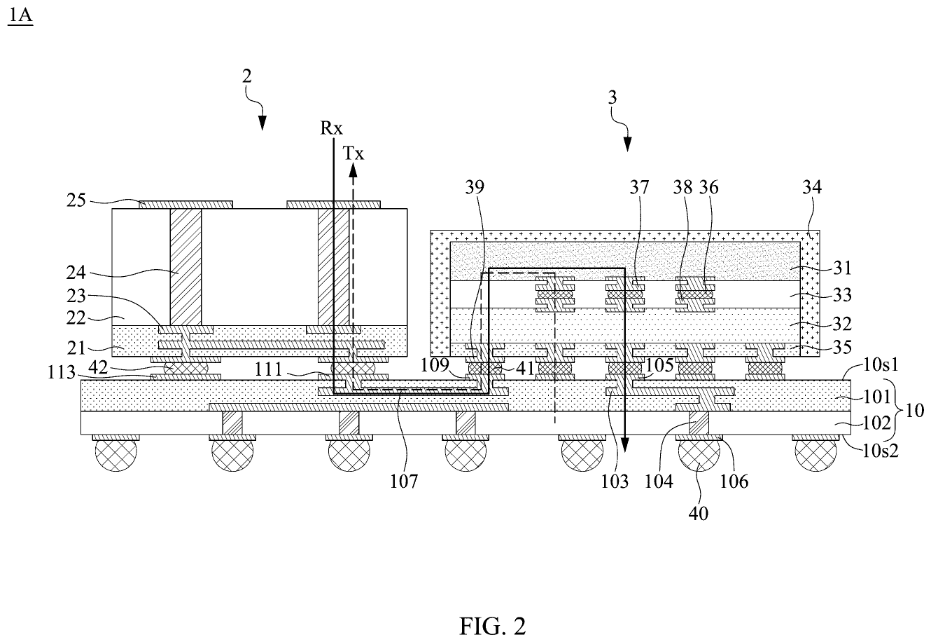

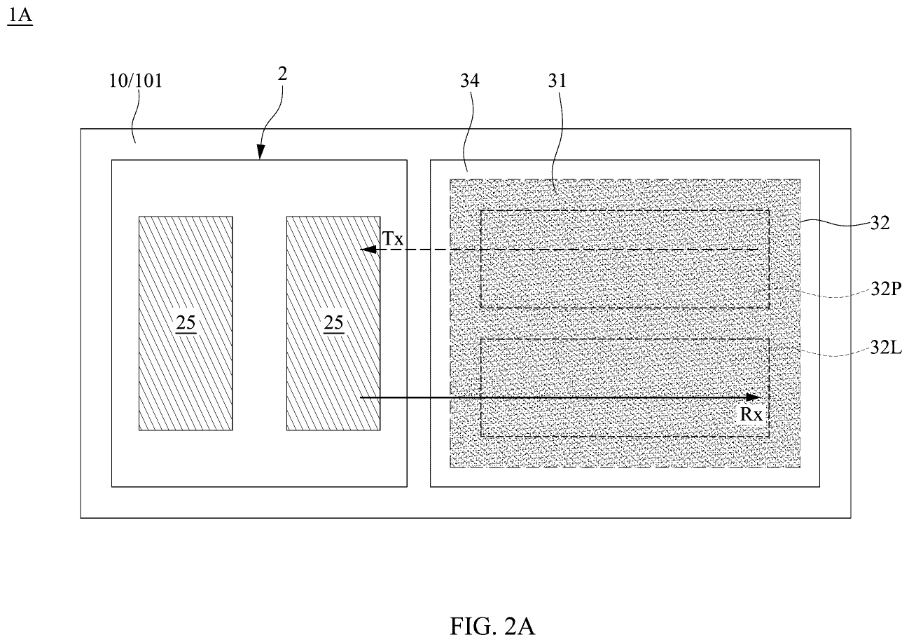

FIG. 2 illustrates signal transmission path(s) of an electronic device (e.g., the electronic device 1A) according to some embodiments of the present disclosure. FIG. 2A illustrates signal transmission path(s) of an electronic device (e.g., the electronic device 1A) according to some embodiments of the present disclosure. The electronic device of FIG. 2 and FIG. 2A is identical to the electronic device 1A in FIGS. 1 and 1A, except that FIG. 2 and FIG. 2A shows the cross-sectional view and the top view of signal transmission paths, respectively. Therefore, some detailed descriptions may refer to corresponding preceding paragraphs and are not repeated hereinafter for conciseness, with differences therebetween as follows.

As shown in FIGS. 2 and 2A, the antenna pattern 25, the antenna component 2, the electronic component (or the power amplifier) 32, and the electronic component (or the radio frequency circuit) 31 may be configured to define a signal transmission path Tx. In other words, the signal transmission path Tx may be established in the antenna pattern 25, the antenna component 2, the electronic component (or the power amplifier) 32, and the electronic component (or the radio frequency circuit) 31 in order. The electronic component (or the radio frequency circuit) 31, the electronic component (or the low noise amplifier) 32, the antenna component 2, and the antenna pattern 25 may be configured to define a signal receiving path Rx. In other words, the signal receiving path Rx may be established in the electronic component (or the radio frequency circuit) 31, the electronic component (or the low noise amplifier) 32, the antenna component 2, and the antenna pattern 25 in order. The signal transmission path Tx and the signal receiving path Rx may be established through the interconnection structure 107 of the redistribution layer 101 of the carrier 10. The electronic component 32 may be disposed between the electronic component 31 and the carrier 10, such that the signal transmission path Tx (or the signal receiving path Rx) between the electronic component 32 and the antenna component 2 can be shorter to improve the transmission loss.

As shown in FIG. 2, the signal transmission path Tx and the signal receiving path Rx pass through the same portion of the redistribution layer 101 of the carrier 10 (e.g., the interconnection structure 107) since they overlap each other in the cross-sectional view. The signal transmission path Tx and the signal receiving path Rx actually pass through different portions of the redistribution layer 101 of the carrier 10 as shown in FIG. 2A.

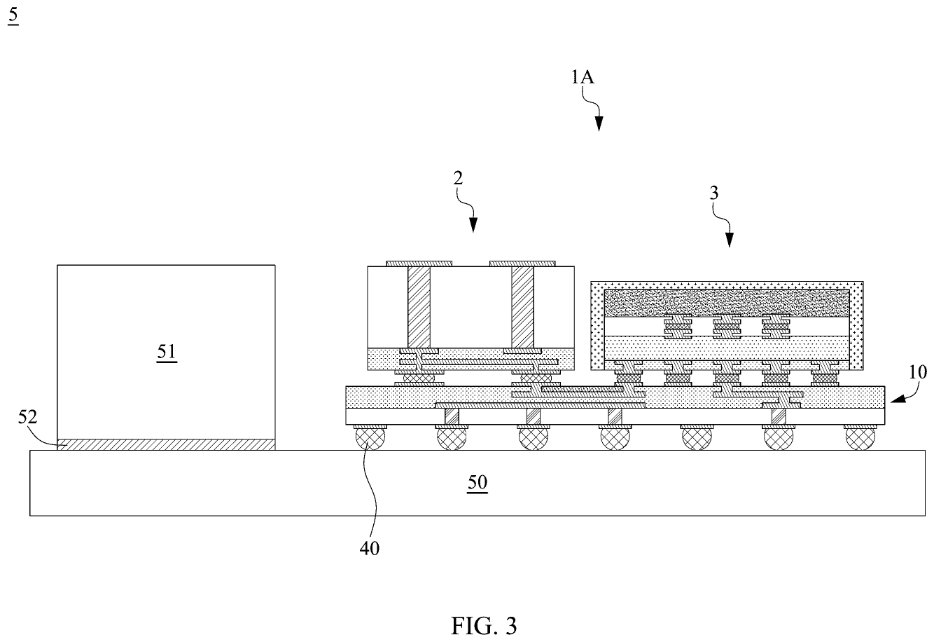

FIG. 3 is a cross-sectional view of an electronic device 5 according to some embodiments of the present disclosure. The electronic device 5 may include the electronic device 1A, a circuit board 50, and a semiconductor die 51. The electronic device 1A may be mounted on the circuit board 50 through the terminals 40. The electronic device 1A may be electrically connected to the circuit board 50. The semiconductor die 51 may be attached to the circuit board 50 through an adhesive layer 52. The semiconductor die 51 may be electrically connected to the circuit board 50. The electronic device 1A may be electrically connected to the semiconductor die 51 through the circuit board 50.

The semiconductor die 51 may include, for example, a central processing unit (CPU), a microprocessor unit (MPU), a graphics processing unit (GPU), a microcontroller unit (MCU), an application-specific integrated circuit (ASIC), a field-programmable gate array (FPGA), or another type of integrated circuit. In some embodiments, the semiconductor die 51 may include one or more processing elements and one or more memory elements electrically connected to the processing elements. The processing element(s) and the memory element(s) may be divided from or originate in a monolithic processing unit (e.g., a CPU, an MPU, a GPU, an MCU, an ASIC, or the like). In some embodiments, the processing element may be a CPU chiplet, an MCU chiplet, a GPU chiplet, an ASIC chiplet, or the like. The memory element may be a cache memory.

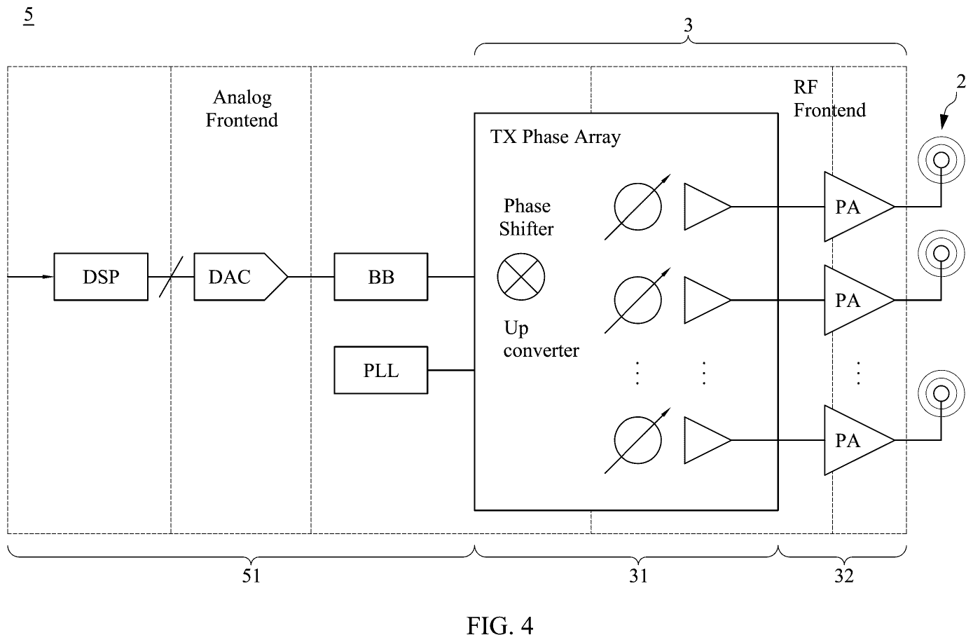

FIG. 4 is a schematic diagram of an electronic device (e.g., the electronic device 5) according to some embodiments of the present disclosure. FIG. 4 shows a transmission scheme of the electronic device which includes transmitting a signal from the semiconductor die 51 to the antenna component 2 through the transceiver 3. The semiconductor die 51 may include a digital signal processing unit DSP, a digital-analog converter DAC, a base band unit BB, and a phase-locked loop unit PLL. The digital signal processing unit DSP involves the use of algorithms and mathematical techniques to process and analyze digital signals. The digital-analog converter DAC may be configured to convert the digital signals from the DSP into analog signals. The baseband processor BB may be configured to manage the physical layer of a communication system (e.g., the electronic device 5), including tasks such as modulation, demodulation, encoding, and decoding of data. The phase-locked loop unit PLL may generate an output signal whose phase is related to the phase of an input signal by comparing the phase of the input signal to the phase of a voltage-controlled oscillator (VCO) and using the difference to adjust the frequency of the VCO.

The semiconductor die 51 may include one or more processors which implement one or more instructions to fulfil the function of the digital signal processing unit DSP, the digital-analog converter DAC, the baseband processor BB, and the phase-locked loop unit PLL. The instructions may be stored in the memory of the semiconductor die 51 in the form of computer program codes.

The electronic component 31 may include a phase array having a plurality of phase shifters. The electronic component 31 may further include an up converter configured to convert a lower frequency signal to a higher frequency. The electronic component 32 may include an array of power amplifiers, each of which is connected to a respective one of the phase shifters of the electronic component 31.

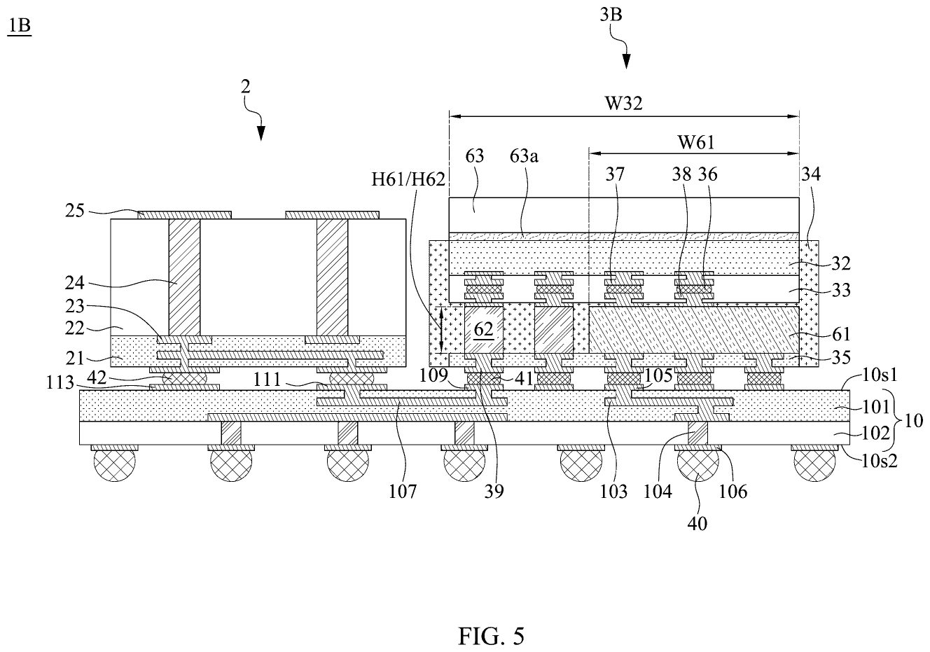

FIG. 5 is a cross-sectional view of an electronic device 1B according to some embodiments of the present disclosure. The electronic device 1B of FIG. 5 is similar to the electronic device 1A in FIG. 1. Therefore, some detailed descriptions may refer to corresponding preceding paragraphs and are not repeated hereinafter for conciseness, with differences therebetween as follows.

The electronic device 1B may include a transceiver 3B, rather than the transceiver 3 of the electronic device 1A. The transceiver 3B may include an electronic component 61, the electronic component 32, the underfill 33, the encapsulation layer 34, the dielectric layer 35, the connection elements 36, and the conductive elements 37, 38, and 39.

The electronic component 61 may be similar to the electronic component 31 in terms of its function and material. The electronic component 32 may be disposed over the electronic component 61. The electronic component 61 may be disposed between the electronic component 32 and the carrier 10. The electronic component 61 may have a width W61 and the electronic component 32 may have a width W32 different from the width W61. The width W32 may be greater than the width W61. The width W61 may be smaller than the width W32.

The electronic component 61 and the electronic component 32 are arranged to enhance the thermal dissipation of the electronic device 1A. The electronic component 32 may be stacked over the electronic component 61. The transceiver 3B may further include a thermal dissipation structure 63 disposed over the electronic component 61 and the electronic component 32. The thermal dissipation structure 63 may be connected to the electronic component 32 through a thermal adhesive layer 63a. The thermal dissipation structure 63 may be configured to enhance the thermal dissipation from the electronic component 32 to an external environment. The thermal dissipation structure 63 may be made of metal, such as copper, gold, silver, aluminum, titanium, tantalum, or the like. The thermal adhesive layer 63a may include, for example, sintered silver.

In order to transmit signals from the antenna component 2 to the electronic component 32 before the signals reaching the electronic component 61, the transceiver 3B further includes a plurality of conductive elements 62 disposed below the electronic component 32. The conductive elements 62 and the electronic component 61 may be arranged side by side. The conductive elements 62 may be encapsulated by the encapsulation layer 34. A height H62 of the conductive elements 62 and a height H61 of the electronic component 61 may be substantially the same. The conductive elements 62 may include a plurality of conductive pillars. The conductive elements 62 may be made of metal, such as copper, gold, silver, aluminum, titanium, tantalum, or the like.

At least two of the antenna component 2, the electronic component (or the power amplifier) 32, and the electronic component (or the radio frequency circuit) 61 may be free from overlapping each other. In some embodiments, the antenna component 2 may be free from overlapping the electronic component (or the power amplifier) 32 in a direction substantially perpendicular to the first surface 10s1 of the carrier 10. In some embodiments, the antenna component 2 may be free from overlapping the electronic component (or the radio frequency circuit) 61 in a direction substantially perpendicular to the first surface 10s1 of the carrier 10. In some embodiments, the electronic component (or the power amplifier) 32 may overlap the electronic component (or the radio frequency circuit) 61 in a direction substantially perpendicular to the first surface 10s1 of the carrier 10.

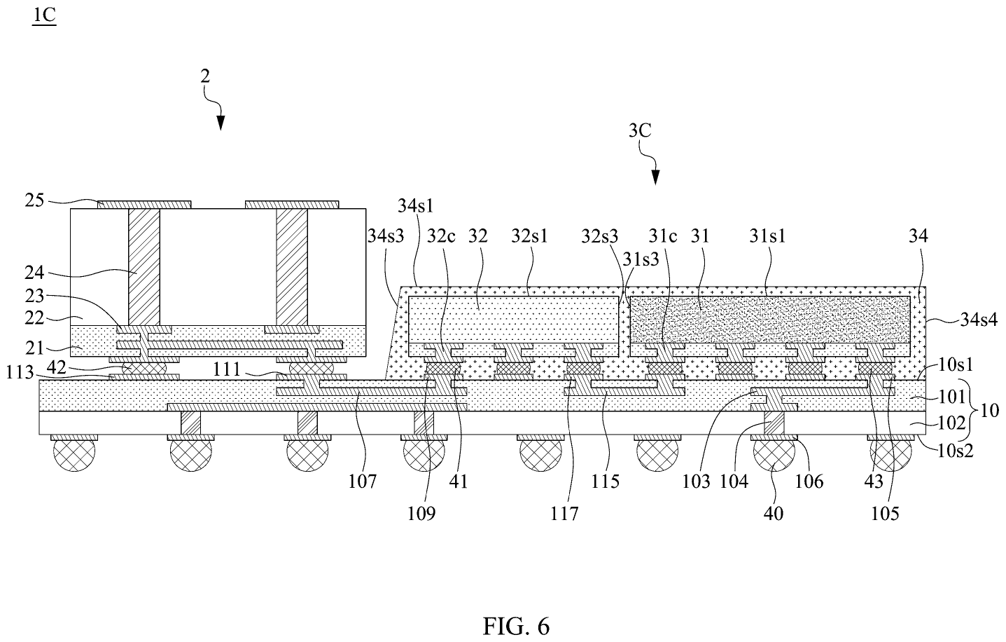

FIG. 6 is a cross-sectional view of an electronic device according to some embodiments of the present disclosure. The electronic device 1C of FIG. 6 is similar to the electronic device 1A in FIG. 1. Therefore, some detailed descriptions may refer to corresponding preceding paragraphs and are not repeated hereinafter for conciseness, with differences therebetween as follows.

As shown in FIG. 6, the electronic component 31 and the electronic component 32 may be disposed side by side. The electronic component 31 may have a surface (or a top surface) 31s1 facing away from the first surface 10s1 of the carrier 10. The electronic component 32 may have a surface (or a top surface) 32s1 facing away from the first surface 10s1 of the carrier 10. The top surface 31s1 and the top surface 32s1 may be substantially coplanar. The electronic component 31 may have a lateral surface 31s3 and the electronic component 32 may have a lateral surface 32s3. The lateral surface 31s3 may face toward the lateral surface 32s3.

The encapsulation layer 34 may encapsulate or cover the electronic component 31 and the electronic component 32. The encapsulation layer 34 may have a top surface 34s1 facing away from the first surface 10s1 of the carrier 10. The encapsulation layer 34 may have a first lateral surface 34s3 facing the antenna component 2 and slanted with respect to the top surface 34s1. The encapsulation layer 34 may have a second lateral surface 34s4 opposite to the first lateral surface 34s3 and substantially perpendicular to the top surface 34s1. The first lateral surface 34s3 and the second lateral surface 34s4 may not be parallel.

The electronic component 31 may be electrically connected to the electronic component 32 by the carrier 10. The redistribution layer 101 may further include an interconnection structure 115 to connect the electronic component 31 and the electronic component 32. The carrier 10 may include a plurality of conductive pads (or pads) 117 and 119. The conductive pads 117 may electrically connect the electronic component 32 to the interconnection structure 115. The conductive pads 119 may electrically connect the electronic component 31 to the interconnection structure 115. The electronic component 31 may include a plurality of conductive elements 31c electrically connected to the carrier 10 through the connection elements 41. The electronic component 32 may include a plurality of conductive elements 32c electrically connected to the carrier 10 through the connection elements 41. The interconnection structure 115 may be made of metal, such as copper, gold, silver, aluminum, titanium, tantalum, or the like. The conductive pads 117 and 119 may be made of metal, such as copper, gold, silver, aluminum, titanium, tantalum, or the like. The conductive elements 31c and 32c may be made of metal, such as copper, gold, silver, aluminum, titanium, tantalum, or the like.

At least two of the antenna component 2, the electronic component (or the power amplifier) 32, and the electronic component (or the radio frequency circuit) 31 may be free from overlapping each other. In some embodiments, the antenna component 2 may be free from overlapping the electronic component (or the power amplifier) 32 in a direction substantially perpendicular to the first surface 10s1 of the carrier 10. In some embodiments, the antenna component 2 may be free from overlapping the electronic component (or the radio frequency circuit) 31 in a direction substantially perpendicular to the first surface 10s1 of the carrier 10. In some embodiments, the electronic component (or the power amplifier) 32 may be free from overlapping the electronic component (or the radio frequency circuit) 31 in a direction substantially perpendicular to the first surface 10s1 of the carrier 10.

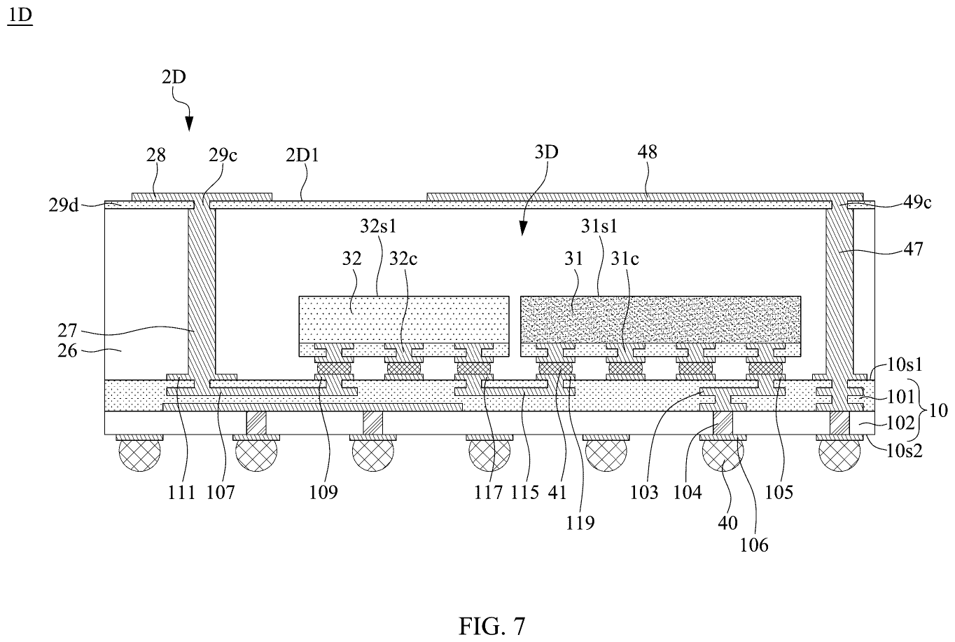

FIG. 7 is a cross-sectional view of an electronic device 1D according to some embodiments of the present disclosure. The electronic device 1D of FIG. 7 is similar to the electronic device 1C in FIG. 6. Therefore, some detailed descriptions may refer to corresponding preceding paragraphs and are not repeated hereinafter for conciseness, with differences therebetween as follows.

The electronic device 1D may include an antenna component 2D and a transceiver 3D. The antenna component 2D may include an encapsulation layer 26, a through-via 27, an antenna pattern 28, a connection 29c, and a dielectric layer 29d.

The encapsulation layer 26 may encapsulate the electronic component 31 and the electronic component 32. The encapsulation layer 26 of the antenna component 2D may contact the carrier 10 at the first surface 10s1. The through-via 27 may extend through the encapsulation layer 26 to connect the carrier 10 and the antenna pattern 28. The connection 29c may connect the through-via 27 and the antenna pattern 28. The connection 29c may be disposed in the dielectric layer 29d.

In some embodiments, the encapsulation layer 26 may include an epoxy resin including fillers, a molding compound (e.g., an epoxy molding compound or another molding compound), polyimide, a phenolic compound or material, a material including silicone dispersed therein, or a combination thereof.

The antenna component 2D may further include a through-via 47, a conductive layer 48, and a connection 49c. The through-via 47 may extend through the encapsulation layer 26 to connect the carrier 10 and the conductive layer 48. The connection 49c may connect the through-via 47 and the conductive layer 48. The connection 49c may be disposed in the dielectric layer 29d. The conductive layer 48 may be an antenna pattern. The antenna component 2D may be configured to receive or transmit signals through the antenna pattern 28 and the conductive layer 48. In some embodiments, the conductive layer 48 may be a shielding layer biased at a reference voltage through the through-via 27 and the carrier 10. The shielding layer may be configured to shield the electronic component 31 and the electronic component 32 of the transceiver 3D from the electromagnetic waves of an external environment. The shielding layer may be configured to shield an external device from the electronic component 31 and the electronic component 32 of the transceiver 3D.

The antenna component 2D may have a top surface 2D1. The antenna pattern 28 may be disposed at the top surface 2D1. The antenna pattern 28 may be disposed over the dielectric layer 29d. The antenna pattern 28 may include a patch antenna. The conductive layer 48 may be disposed at the top surface 2D1. The conductive layer 48 may be disposed over the dielectric layer 29d. The conductive layer 48 may include a patch antenna.

The electronic component 31 and the electronic component 32 of the transceiver 3D may be arranged to enhance the thermal dissipation of the electronic device 1D. The electronic component 31 and the electronic component 32 may be disposed side by side, similar to the arrangement in FIG. 6. The top surface 31s1 of the electronic component 31 and the top surface 32s1 of the electronic component 32 may be at an elevation lower than the top surface 2D1 of the antenna component 2D. The transceiver 3D is integrated into the antenna component 2D. Thus, the size (e.g., the dimension in X axis or Y axis) of the electronic device 1D can be reduced.

At least two of the antenna component 2D, the electronic component (or the power amplifier) 32, and the electronic component (or the radio frequency circuit) 31 may be free from overlapping each other. In some embodiments, the antenna component 2D may overlap the electronic component (or the power amplifier) 32 in a direction substantially perpendicular to the first surface 10s1 of the carrier 10. In some embodiments, the antenna component 2D may overlap the electronic component (or the radio frequency circuit) 31 in a direction substantially perpendicular to the first surface 10s1 of the carrier 10. In some embodiments, the electronic component (or the power amplifier) 32 may be free from overlapping the electronic component (or the radio frequency circuit) 31 in a direction substantially perpendicular to the first surface 10s1 of the carrier 10.

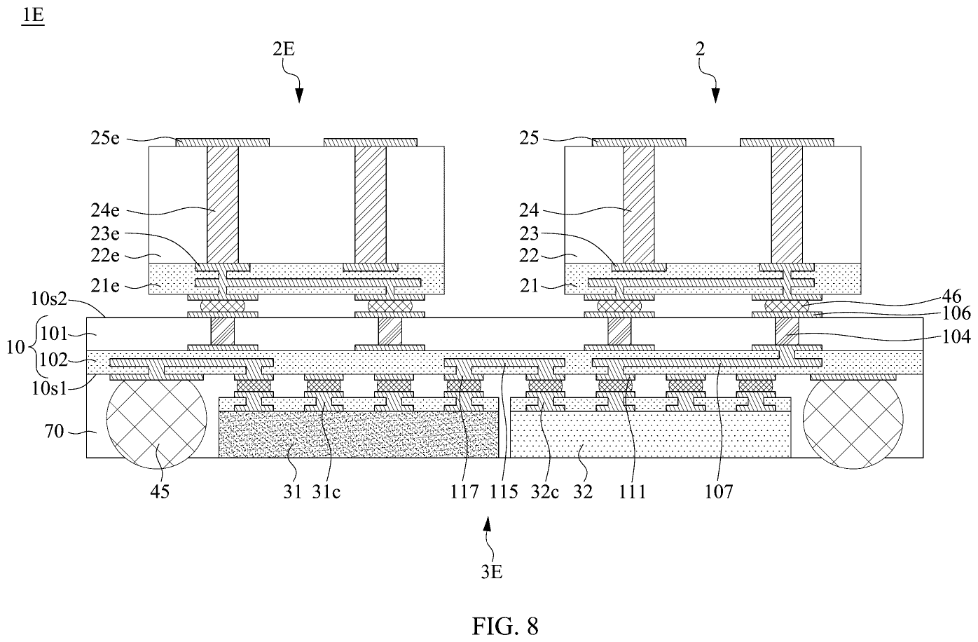

FIG. 8 is a cross-sectional view of an electronic device 1E according to some embodiments of the present disclosure. The electronic device 1E of FIG. 8 is similar to the electronic device 1A in FIG. 1. Therefore, some detailed descriptions may refer to corresponding preceding paragraphs and are not repeated hereinafter for conciseness, with differences therebetween as follows.

The electronic device 1E may include the antenna component 2, an antenna component 2E, the carrier 10, a transceiver 3E, an encapsulation layer 70, and a plurality of terminals 45. The antenna component 2E may be similar or identical to the antenna component 2.

The antenna component 2E may include a redistribution layer 21e, a substrate 22e, a plurality of traces 23e, a through-via 24e, and an antenna pattern 25e. The redistribution layer 21e may have a similar structure or material to the redistribution layer 21. The substrate 22e may have a similar structure or material to the substrate 22. The plurality of traces 23e may have a similar structure or material to the traces 23. The through-via 24e may have a similar structure or material to the through-via 24. The antenna pattern 25e may have a similar structure or material to the antenna pattern 25.

The electronic device 1E may include a plurality of connection elements 46 between the carrier 10 and the antenna component 2 (or the antenna component 2E). The antenna component 2E and the antenna component 2 may be connected to the carrier 10 through the connection elements 46. The antenna component 2E and the antenna component 2 may be connected to the transceiver 3E through the carrier 10. The antenna component 2E and the antenna component 2 may be arranged side by side. The antenna component 2E and the antenna component 2 may collaborately receive or transmit signals. The antenna component 2E and the antenna component 2 may form an antenna array. The transceiver 3E may include the electronic component 31 and the electronic component 32 arranged side by side. The encapsulation layer 70 may encapsulate the electronic component 31 and the electronic component 32. The encapsulation layer 70 may encapsulate the terminals 45. The terminals 45 may connect to an external electronic device (not shown).

In some embodiments, the encapsulation layer 70 may include an epoxy resin including fillers, a molding compound (e.g., an epoxy molding compound or another molding compound), polyimide, a phenolic compound or material, a material including silicone dispersed therein, or a combination thereof. The terminals 45 and the connection elements 46 may include solder balls, controlled collapse chip connection (C4) bumps, a ball grid array (BGA), or a land grid array (LGA).

The transceiver 3E may be disposed over the first surface 10s1 of the carrier 10. The antenna component 2E and the antenna component 2 may be disposed over the second surface 20s2 of the carrier 10. The transceiver 3E and the antenna components 2 and 2E may be disposed at different sides of the carrier 10. The electronic component 31 and the electronic component 32 of the transceiver 3E may be arranged to enhance the thermal dissipation of the electronic device 1E. The electronic component 32 may be exposed by the encapsulation layer 70, such that the thermal dissipation of the electronic component 32 can be improved.

The transceiver 3E and the antenna components 2 and 2E are integrated in a vertical direction, such that the size (e.g., the dimension in X axis or Y axis) of the electronic device 1E can be reduced.

At least two of the antenna components 2 and 2E, the electronic component (or the power amplifier) 32, and the electronic component (or the radio frequency circuit) 31 may be free from overlapping each other. In some embodiments, the antenna component 2 may overlap the electronic component (or the power amplifier) 32 in a direction substantially perpendicular to the first surface 10s1 of the carrier 10. In some embodiments, the antenna component 2E may overlap the electronic component (or the radio frequency circuit) 31 in a direction substantially perpendicular to the first surface 10s1 of the carrier 10. In some embodiments, the electronic component (or the power amplifier) 32 may be free from overlapping the electronic component (or the radio frequency circuit) 31 in a direction substantially perpendicular to the first surface 10s1 of the carrier 10.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to #1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to =0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a carrier having a first surface;
an antenna component disposed over the first surface of the carrier; and
a transceiver disposed over the first surface of the carrier and configured to transmit signals to the antenna component by the carrier.

2. The electronic device of claim 1, wherein the transceiver has a top surface, the antenna component has a top surface, wherein an elevation of the top surface of the transceiver is between an elevation of the top surface of the antenna component and an elevation of the first surface of the carrier.

3. The electronic device of claim 1, wherein the transceiver comprises a first electronic component configured to operate in a first function and a second electronic component separated from the first electronic component, wherein the second electronic component is configured to operate in a second function distinct from the first function.

4. The electronic device of claim 3, wherein the first electronic component is electrically connected to the second electronic component by the carrier.

5. The electronic device of claim 3, further comprising a conductive layer disposed outside the carrier and electrically connecting the first electronic component to the second electronic component.

6. The electronic device of claim 3, wherein the second electronic component is stacked over the first electronic component, and a first width of the first electronic component is smaller than a second width of the second electronic component.

7. The electronic device of claim 1, wherein the carrier comprises an interconnection structure extending in a direction substantially parallel to the first surface of the carrier, wherein the interconnection structure electrically connects the transceiver to the antenna component.

8. The electronic device of claim 7, wherein the antenna component has a lateral surface perpendicular to the first surface of the carrier, and an imaginary extension line of the lateral surface passes through the interconnection structure.

9. An electronic device, comprising:
an antenna component;
a power amplifier electrically connected to the antenna component; and
a radio frequency circuit electrically connected to the power amplifier,
wherein at least two of the antenna component, the power amplifier, and the radio frequency circuit are free from overlapping each other.

10. The electronic device of claim 9, wherein the antenna component comprises an antenna pattern disposed on a top surface of the antenna component, wherein the antenna pattern is free from overlapping the power amplifier in a direction substantially perpendicular to the top surface of the antenna component.

11. The electronic device of claim 10, wherein the antenna pattern is free from overlapping the radio frequency circuit in a direction substantially perpendicular to the top surface of the antenna component.

12. The electronic device of claim 10, wherein the antenna pattern, the antenna component, the power amplifier, and the radio frequency circuit are configured to define a signal transmission path.

13. The electronic device of claim 12, further comprising a low noise amplifier, wherein the radio frequency circuit, the low noise amplifier, the antenna component, and the antenna pattern are configured to define a signal receiving path.

14. The electronic device of claim 13, wherein the power amplifier and the low noise amplifier are integrated.

15. The electronic device of claim 9, further comprising an encapsulation layer covering the power amplifier and the radio frequency circuit.

16. An electronic device, comprising:
a carrier;
an antenna component disposed over the carrier;
a transceiver comprising a first electronic component with a first technical node disposed over the carrier and a second electronic component with a second technical node disposed over the carrier,
wherein the first electronic component is separated from the second electronic component and configured to enhance a thermal dissipation of the second electronic component.

17. The electronic device of claim 16, wherein the first technical node includes a CMOS technical node, and the second technical node includes an III-V technical node.

18. The electronic device of claim 16, wherein the second electronic component is disposed between the first electronic component and the carrier.

19. The electronic device of claim 16, wherein the first electronic component is stacked over the second electronic component, and the antenna component has a first lateral surface facing the second electronic component and the first electronic component.

20. The electronic device of claim 16, wherein the electronic device is electrically connected to an external device through an external circuit board.
